(19) United States
(12) Patent Application Publication
(10) Pub. No.: US 2025/0005241 A1
(43) Pub. Date: Jan. 2, 2025

(54) BUILDING AND REDACTION OF UNIVERSAL FUNCTIONAL MODULES

(71) Applicant: University of Florida Research Foundation, Incorporated, Gainesville, FL (US)

(72) Inventors: Mark M. Tehranipoor, Gainesville, FL (US); Mohammad Sazadur Rahman, Gainesville, FL (US); Kimia Zamiri Azar, Gainesville, FL (US); Hadi Mardani Kamali, Gainesville, FL (US); Fahim Rahman, Gainesville, FL (US); Farimah Farahmandi, Gainesville, FL (US); Rui Guo, Gainesville, FL (US)

(21) Appl. No.: 18/745,588

(22) Filed: Jun. 17, 2024

Related U.S. Application Data
(60) Provisional application No. 63/521,983, filed on Jun. 20, 2023.

(51) Int. Cl. G06F 30/327

(52) U.S. Cl. CPC G06F 30/327

(57) ABSTRACT

Embodiments relate to building and redacting of universal functional modules (UFMs). An example method includes receiving a register-transfer-level (RTL) description of an integrated circuit (IC) asset, generating a split RTL description comprising a plurality of sub-circuits by splitting the RTL description of the IC asset, and generating a plurality of replaced sub-circuits by replacing a subset of the plurality of sub-circuits with multiplexor (MUX)-based lookup-tables (LUTs). Determining the subset of the plurality of sub-circuits to replace with MUX-based LUTs includes identifying, based at least in part on performing a conflict graph coloring, non-interference sub-circuits of the plurality of sub-circuits, generating a plurality of scores by generating a score for each non-interference sub-circuit and based at least in part on the non-interference sub-circuit interaction with other sub-circuits, and based at least in part on a desired number of sub-circuits to replace and the plurality of scores, determining the subset.

### CROSS-REFERENCE TO RELATED APPLICATIONS

The present application claims priority to U.S. Provisional Ser. No. 63/521,983, titled “BUILDING AND REDACTION OF UNIVERSAL FUNCTIONAL MODULES,” filed Jun. 20, 2023, the entire contents of which are incorporated herein by reference.

### BACKGROUND

Due to the complexity of modern System-on-Chips (SoCs) and the prevalence of design reuse, it is common for IC designers to license high-level intellectual property (IP) cores in the form of soft (RTL), firm (netlist), or hard (GDSII) IPs for their SoC designs. As a result of globalization, costs and time-to-market is improved. However, the inclusion of third-party IPs (3PIPs) in a cooperative model involves multiple entities around the world and introduces multiple security threats at different semiconductors IC supply chains stages, such as IP piracy, Trojan insertion, counterfeiting, and overproduction. In response to these security threats, active design-for-trust (DfTr) strategies have become increasingly prominent since passive countermeasures like patents, copyrights, and watermarking have failed to provide any protection. Amongst them, the logic locking is an effective solution, and its main principle is to insert additional key gates in the circuit to achieve the purpose of hiding the function of IP/IC. Typically, after the chip is manufactured, key inputs are configured by tamper-proof memories on the chip. As a result, the design will only work properly if the correct key input value is provided.

Over the last decade, logic locking has made tremendous advances. However, all of them are vulnerable to Boolean satisfiability (SAT)-based key extraction attack. Several SAT-resistant logic obfuscations have recently been proposed, including point-function based and routing-based. Logical locking techniques are often vulnerable to other attacks, either structural or ML-based, showing that the adversary can effectively define different attack procedures. Also, sequential or timing-based logic locking of IP/IC has also been investigated in the literature. Nevertheless, these countermeasures are vulnerable to other derivatives of the SAT attacks, showing the critical need to develop countermeasures to such attacks, particularly SAT and its derivatives.

In recent years, a coarse-grained form of logic locking has gained momentum, in which SoC-level redaction is performed using an embedded FPGA (eFPGA). In this case, the user selects the whole or a portion of the asset IP (e.g., security-critical modules) for redaction and implements them in an eFPGA embedded into the SoC. The bitstream that programs the eFPGA becomes the secret key, and the attacker must restore the complete bitstream to make the whole system and the eFPGA function correctly. Concurrently, researchers challenged the practical applicability of traditional logic locking methods considering the plethora of attacks and formally proved that universal circuits can only achieve the indistinguishable security of logic locking at the cost of O(nlogn) area expansion. The area overhead of the proposed eFPGA-based IP redaction methods also validates the required key size. Hence the challenges with eFPGA-based IP protection greatly lie in optimizing the area. There is a need for a unique and completely fine-grained IP redaction method using unit reconfigurable components, such as look-up tables (LUTs).

### SUMMARY

Embodiments herein relate to building and redacting of universal functional modules (UFMs). An example method includes receiving a register-transfer-level (RTL) description of an integrated circuit (IC) asset, generating a split RTL description comprising a plurality of sub-circuits by splitting the RTL description of the IC asset, and generating a plurality of replaced sub-circuits by replacing a subset of the plurality of sub-circuits with multiplexor (MUX)-based lookup-tables (LUTs). Determining the subset of the plurality of sub-circuits to replace with MUX-based LUTs includes identifying, based at least in part on performing a conflict graph coloring, non-interference sub-circuits of the plurality of sub-circuits, generating a plurality of scores by generating a score for each non-interference sub-circuit and based at least in part on the non-interference sub-circuit interaction with other sub-circuits, and based at least in part on a desired number of sub-circuits to replace and the plurality of scores, determining the subset.

The above summary is provided merely for purposes of summarizing some example embodiments to provide a basic understanding of some aspects of the present disclosure. Accordingly, it will be appreciated that the above-described embodiments are merely examples and should not be construed to narrow the scope or the spirit of the present disclosure in any way. It will be appreciated that the scope of the present disclosure encompasses many potential embodiments in addition to those here summarized, some of which will be further described below. Other features, aspects, and advantages of the subject matter will become apparent from the description, the drawings, and the claims.

### BRIEF DESCRIPTION OF THE FIGURES

Having thus described certain example embodiments of the present disclosure in general terms above, non-limiting and non-exhaustive embodiments of the subject disclosure will now be described with reference to the accompanying drawings which are not necessarily drawn to scale. The components illustrated in the accompanying drawings may or may not be present in certain embodiments described herein. Some embodiments may include fewer (or more) components than those shown in the drawings. Some embodiments may include the components arranged in a different way:

FIGS. 1A and 1B depict example eFPGA fabric area overhead, in accordance with embodiments of the present disclosure.

FIGS. 2A, 2B, and 2C depict example cone-based logic redaction, in accordance with embodiments of the present disclosure.

FIG. 3 depicts an example design flow with selective redaction of subcircuits, in accordance with embodiments of the present disclosure.

FIG. 4 depicts example circuit splitter and conflict sub-circuit identification and scoring, in accordance with embodiments of the present disclosure.

FIGS. 5A, 5B, 5C, and 5D depict example circuit splitter and conflict sub-circuit identification, in accordance with embodiments of the present disclosure.

FIG. 6 depicts a number of redacted sub-circuits vs. a SAT attack time vs. a key length for redaction, in accordance with embodiments of the present disclosure.

FIG. 7 depicts an example circuit split algorithm (ALGORITHM 1), in accordance with embodiments of the present disclosure.

FIG. 8 depicts a table (TABLE I) of example benchmark circuits specifications, in accordance with embodiments of the present disclosure.

FIG. 9 depicts a table (TABLE II) of example SAT attack and overhead comparisons, in accordance with embodiments of the present disclosure.

FIG. 10 provides an example overview of a system that can be used to practice embodiments of the present disclosure.

FIG. 11 provides an example computing entity in accordance with some embodiments discussed herein.

FIG. 12 provides an example external computing entity in accordance with some embodiments discussed herein.

### DETAILED DESCRIPTION

Various embodiments of the present disclosure are described more fully hereinafter with reference to the accompanying drawings, in which some, but not all embodiments of the present disclosure are shown. Indeed, the present disclosure may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Terms such as “computing,” “determining,” “generating,” and/or similar words are used herein interchangeably to refer to the creation, modification, or identification of data. Further, “based on,” “based at least in part on,” “based at least on,” “based upon,” and/or similar words are used herein interchangeably in an open-ended manner such that they do not indicate being based only on or based solely on the referenced element or elements unless so indicated. Like numbers refer to like elements throughout.

Embodiments herein provide for a fine-grained IP redaction method using universal circuits. Embodiments herein related to deploying a conflict coloring (e.g., identification) graph-based circuit splitting tool that dissects a target RTL IP into sub-circuits and replaces the selected sub-circuits using LUTs. Unlike the existing methods that select the whole or modules of the asset IP, individual logic cones are redacted and replaced with reconfigurable LUTs. Embodiments herein further provide for a graph-based circuit splitting tool that disintegrates the asset IP into smaller sub-circuits and utilizes a conflict sub-circuit coloring method to efficiently select which sub-circuits should be redacted for better SAT resiliency. Embodiments herein illustrate a varied number of sub-circuit replacements by methods described herein to achieve a timeout (24 hours) and the achieved area overhead is compared with that of eFPGA-based IP redaction. Results herein show that embodiments of the present disclosure can achieve approximately 2 orders of magnitude area gain over eFPGA.

### Threat Model

Similar to the eFPGA-based redaction technique, to assess the robustness of approaches described herein, the traditional Oracle-guided threat model is employed by conducting a SAT attack, in which:
(1) The adversary (either an untrusted foundry or a malicious end-user) has access to the locked netlist. The locked netlist can be obtained by either extracting gate-level netlists from the GDSII or de-processing and reverse-engineering the chip.
(2) To generate correct outputs, the adversary must have access to one unlocked IC (oracle). It is possible to acquire such an IC from the open market, an in-field system, or a rogue insider within a supply chain.
(3) In addition, scan chains can be used to partition sequential circuits into combinations of smaller circuits, then the attacker can use SAT attacks independently on each.

In this strong threat model, an attacker has no restrictions on information other than the correct unlocking key.

### Programmable Fabrics-Based Redaction

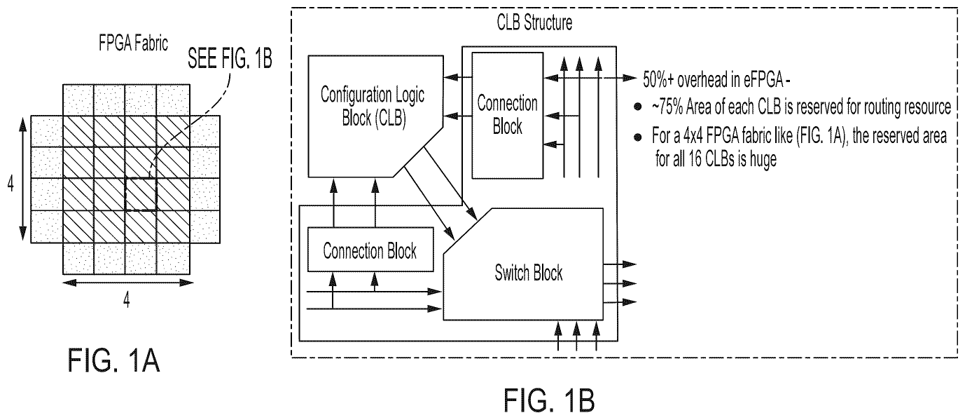

Researchers have explored programmable fabrics to improve the security of obfuscation strategies, primarily as a countermeasure against state-of-the-art attacks, including SAT (and its variants), structural-based attacks, machine learning (ML)-based attacks, etc. As stated in the previous section, the designer implements only a portion of the design into a programmable fabric in this technique. At the same time, the remaining part follows a conventional ASIC design and fabrication flow. As shown in FIG. 1A, eFPGAs consist of Configurable Logic Blocks (CLBs) (e.g., FIG. 1B) that contain look-up tables (LUTs), flip-flops, and routing logic (MUX-based crossbars) programmed to perform any function. To implement configurable routing, FPGAs contain MUX-based switch boxes and connection blocks. This reconfigurability allows the designer to configure the bitstream to implement critical parts of the design after manufacturing, where the bitstream is the key to the design. In this way, the design can be manufactured by any untrusted offshore foundry without the eFPGA being programmed, which makes the overall design obfuscated. Once the design is fabricated, a trusted facility programs the eFPGA to recover the correct functionality of the whole design.

Inapplicability of eFPGA-Based Logic Redaction

Redactions that utilize programmable fabric-based technologies pose many challenges to designers, such as customizing/selecting fabric configurations, deciding which blocks of IP should be implemented on programmable fabrics, as well as the overhead involved in integration and implementation. One approach involves selecting to redact from a high-level (C-based) design to maximize safety metrics until an area overhead threshold is reached. Another approach involves implementing the generation of the eFPGA fabric by selecting individual modules of the design. Considering the trade-offs between security and other design factors such as area and time, in IP redaction, the selected module (“redaction module”) needs to fit into the eFPGA fabric. Thus, the designer needs to know the resources available for a specific fabric size, and limited resources make it impossible for the designer to choose a target arbitrarily. Alternatively, after determining the redaction module, select the fabric that can meet the size requirements. However, the minimum fabric size can be affected by different factors. The interface of the module (number of inputs and outputs) will affect the number of I/O blocks required, while the number of state elements (registers/flip-flops) will affect the number of CLBs. Either factor will cause the size of the final eFPGA to change, resulting in low utilization of the internal resources of the structure for redaction. Furthermore, eFPGA-based coarse-grained reconfigurability has a significant impact on the area since the number of CLBs and I/O blocks grow nonlinearly with eFPGA fabric size. When a designer makes one of the CLB or I/O blocks meet the minimum requirements, there is often a waste of space for the other. Further, a large amount of area must be dedicated to routing, as shown in FIGS. 1A and 1B, resulting in a smaller effective logic area ratio.

### Example Embodiments

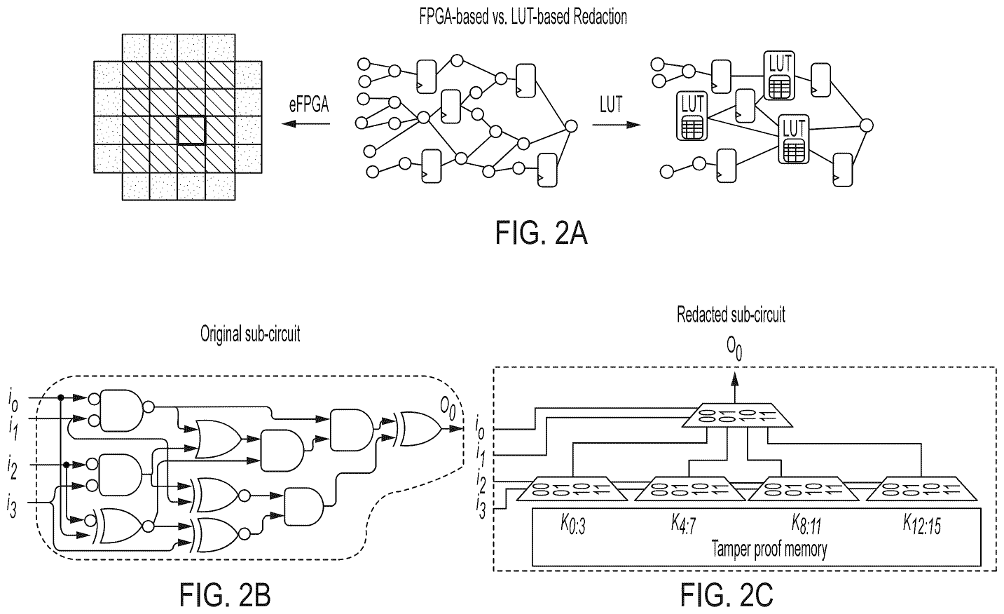

FIGS. 2A, 2B, and 2C depict example differences between eFPGA-based and LUT-based redaction. From eFPGA (consisting of hundreds to thousands of LUTs) to individual LUTs, coarse granularity to fine granularity can be realized. FIGS. 2B and 2C depict how each logic sub-circuit will be mapped to a LUT. In this case, the sub-circuit with 4/1 inputs/output will be redacted by a LUT-4 with 16 configuration bit (K_{0.15}), and, similar to eFPGA-based redaction, this configuration is treated as the secret stored in tamper-proof memory. When eFPGA-based redaction is in place, hundreds of these conversions (e.g., from logic to LUT) will be accomplished surrounded by a huge routing crossbar. However, the embodiments herein demonstrate that instead of mapping a module/IP into an eFPGA fabric, it can be reduced to the sub-circuits of modules/IPs with selective cone-to-LUT redaction.

Compared to eFPGA-based redaction, acting selectively for LUT-based redaction allows for a much more area-efficient redaction. For instance, in FIGS. 2A, 2B, and 2C, a sub-circuit of ten gates is replaced by a MUX-based universal circuit of only five gates (˜50% area gain). Several benchmarks were investigated, which resulted in the following observations:
(i) Splitting the original IP into fine-grained smaller sub-circuits keeps the number of inputs to the sub-circuits at a minimum. Therefore, the size of the replacement universal circuit can be smaller than the original sub-circuit, and eventually, the IP redaction may reduce area.
(ii) As the number of replacements increases, the redacted IP becomes more SAT resilient (stronger obfuscation). However, the area gain from individual replacement adds up and can eventually increase the overall area overhead.

Therefore, a “break-even” point must be achieved for expected resiliency.

### Overview of Flow of Embodiments Herein

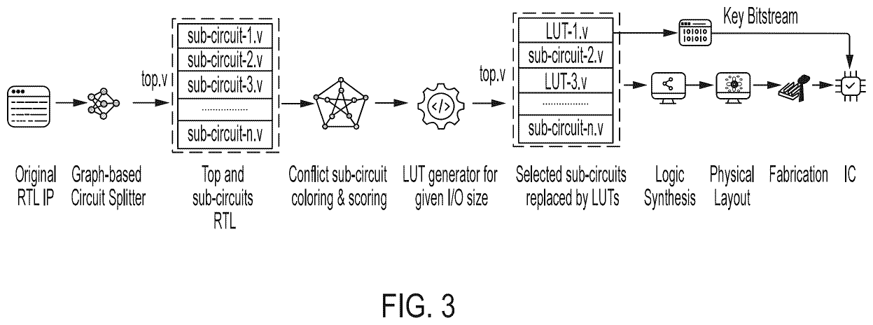

Embodiments herein (also referred to as “EvoLUTe”) aim to split the original circuit as fine-grained as possible so that a number of sub-circuits can be selected for LUT-based redaction, thereby reducing area overhead while keeping the SAT resiliency. The process consists of three components—(i) circuit splitter, (ii) conflict circuit coloring and scoring, and (iii) reconfigurability generation. FIG. 3 shows a high-level overview of a design flow using embodiments of the present disclosure (EvoLUTe). It begins with the processing of the original RTL of the IP asset. Splitting the original IP into smaller sub-circuits keeps the number of inputs to the sub-circuits small, which can make the replacement universal circuit smaller than the original sub-circuit. Hence, embodiments herein deploy a graph-based circuit splitting tool that disintegrates the original RTL IP into smaller sub-circuits in the form of RTLs and creates an RTL (e.g., a “split RTL”) in which the sub-circuits are instantiated to reconstruct the whole IP functionality.

To achieve IP redaction-based hardware obfuscation while keeping the area cost low, embodiments herein propose a selected number of sub-circuits to be replaced by MUX-based LUTs as shown in FIGS. 2A-2C. To select which sub-circuits to be replaced, embodiments herein perform a conflict graph coloring to identify sub-circuits with non-interference. This approach ensures that the attacker encounters each sub-circuit individually and cannot gain any leverage on another sub-circuit by compromising one. Later, embodiments herein assign a score to each non-interference sub-circuit based on their interaction with the other sub-circuits. A higher score defines more interaction with the neighboring sub-circuits. A parser (e.g., a Python parser) is then used to generate the MUX-tree-based universal circuit for the given I/O bandwidth of the sub-circuits and their associated bitstream (key inputs in FIG. 2B). After that, the top-level RTL generated by the circuit splitter tool is utilized to integrate all the sub-circuits and LUTs to realize the whole IP. Later, the conventional ASIC design flow is carried out. Once individual ICs are packaged, a bitstream generated earlier is used to unlock the LUT-based redacted IP functionality.

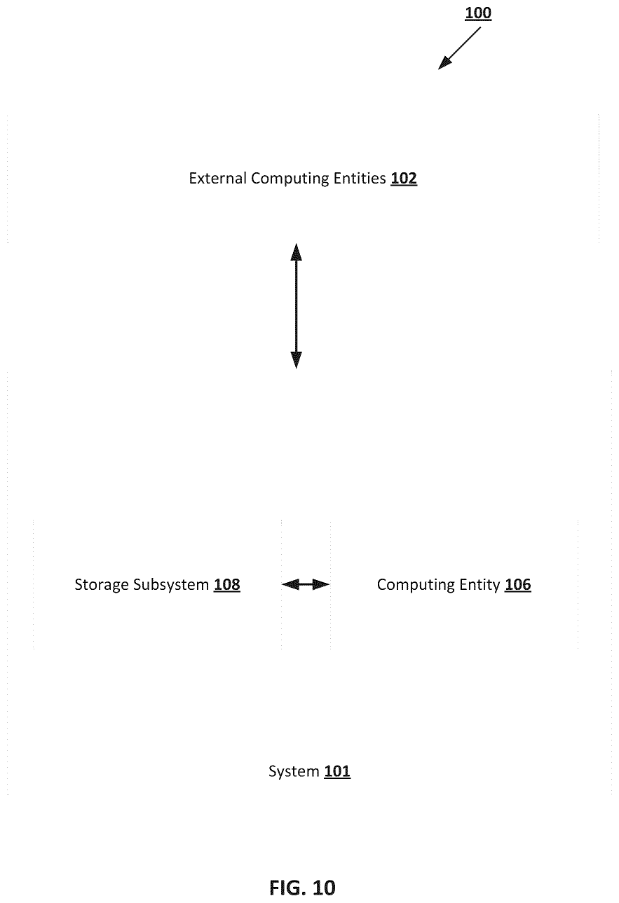

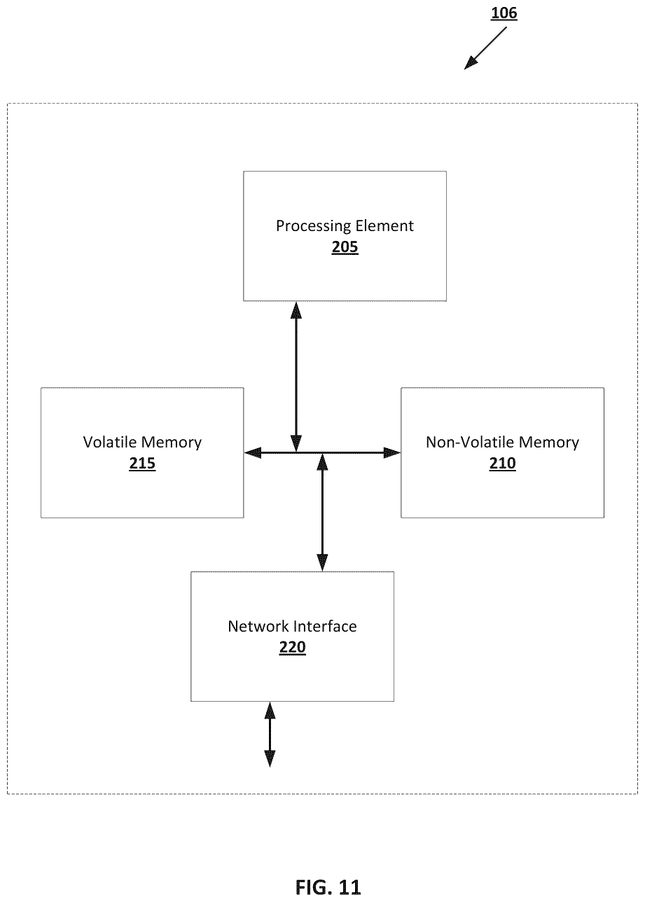

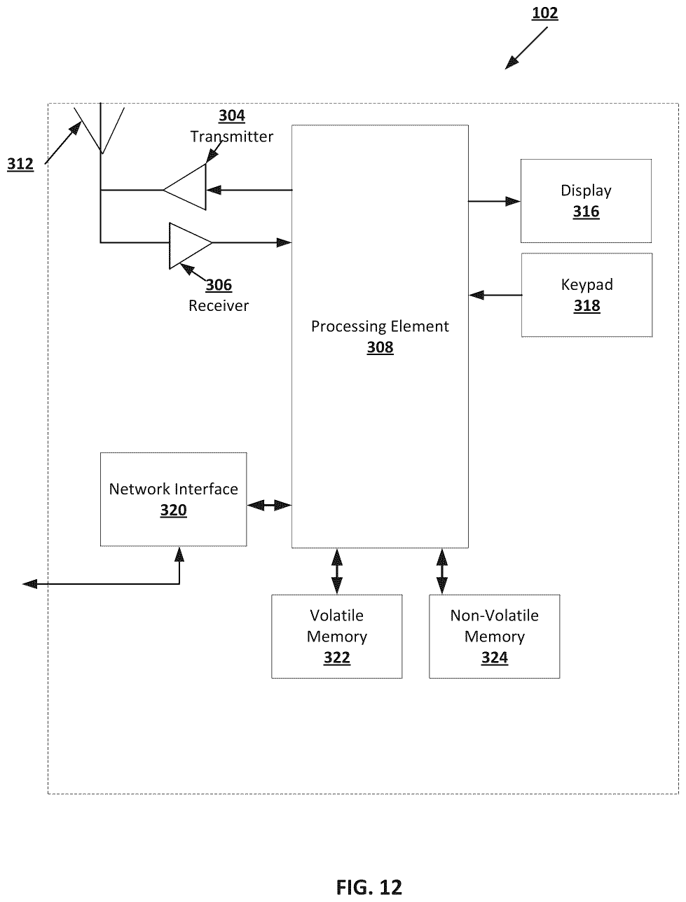

It will be appreciated that any or all of the functions and operations described herein as part of embodiments of the present disclosure can be performed using an example system 100 (e.g., as shown in FIG. 10), and/or apparatuses 106 or 102 (e.g., as shown in FIGS. 11 and 12), and/or some combination of the same.

In contrast to conventional LUT-based obfuscation techniques that have concentrated on the gate to LUT replacement (individual logic gate to individual LUT) (which incurs significant overhead), embodiments herein focus on sub-circuit (logic cone) to LUT replacement by using the proposed splitter and conflict graph coloring techniques (which consistently improve resiliency per incurred overhead).

### Graph-Based Circuit Splitter

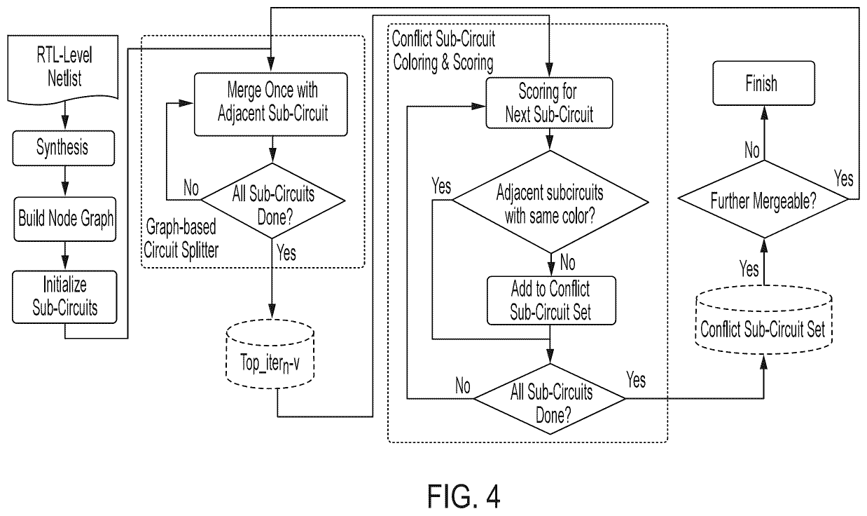

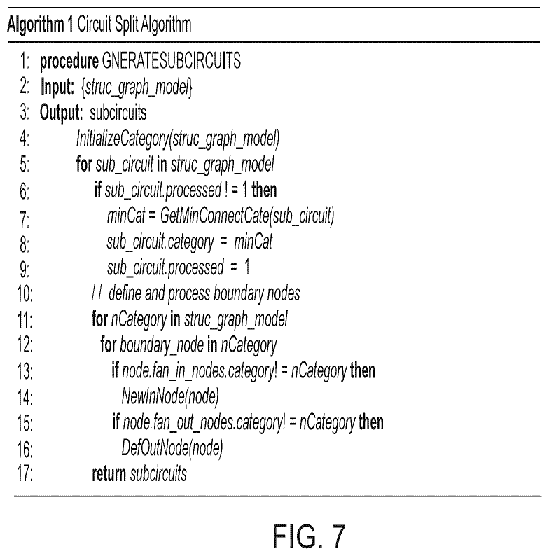

Embodiments herein split a circuit into several sub-circuits and replace one or more with MUX-tree-based LUTs, the result of which is a split RTL. After the initialization step (defining splitting cutting edges and building sub-RTLs), the circuit splitter merges the sub-circuits with their adjacent sub-circuits iteratively. Embodiments herein accomplish these steps very efficiently to maximize the scalability of the framework. To do that, the processing is accomplished in O(n) (n: sub-circuits) where each sub-circuit is processed at most once in an iteration. Additionally, it is enabled with a straight-forward structural and functional verification, to guarantee the correctness of split and merge. The left side of FIG. 4 shows the detailed steps of the splitter, and ALGORITHM 1 (FIG. 7) demonstrates the details of the splitting algorithm.

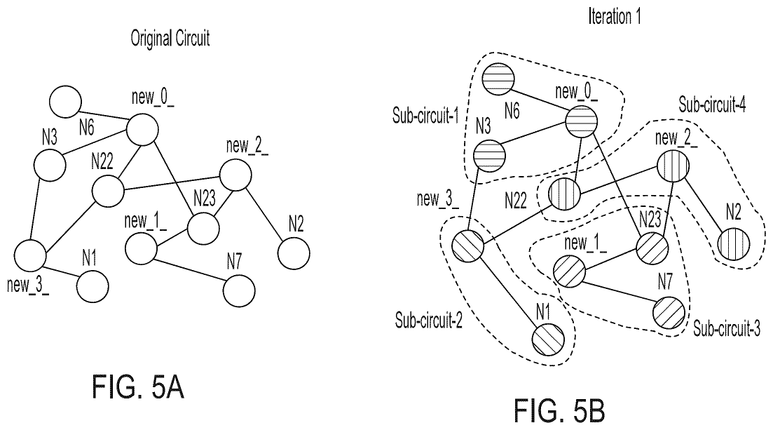

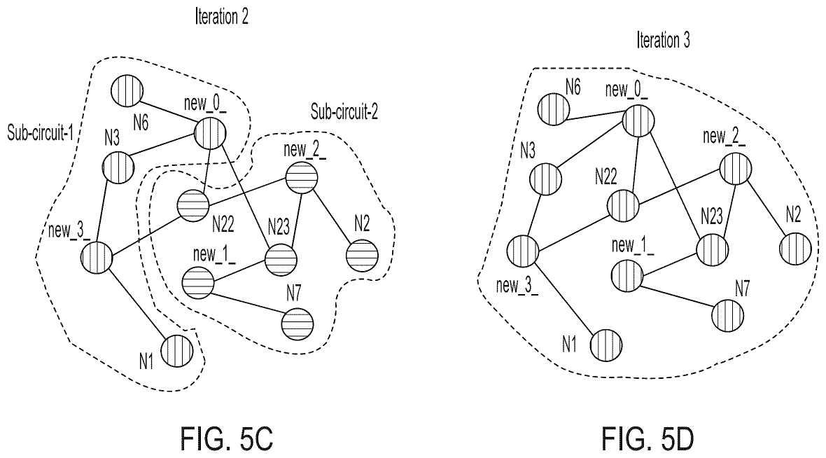

The splitting in embodiments herein (e.g., ALGORITHM 1 (FIG. 7)) has been accomplished iteratively to support multiple degrees of (fine-)granularity. It starts from the initial iteration (iter₀), the size of each sub-circuit will be increased, and accordingly, the number of sub-circuits that built the whole circuit will decrease. So, from iter₀ to (iter_{N}), splitting provides a trend from fine-granularity to coarse-granularity. FIGS. 5A, 5B, 5C, and 5C show an example of iterations (iter₁₋₃) on ISCAS-85 c17. As shown, for iter₁→iter₃, the number of gates per each sub-circuit is {2-3}, {5-6}, and 11, respectively, showing that granularity is getting coarse. On the other side, with coarse-granularity, it can be seen that the number of sub-circuits that build the whole circuit decreases from 4 to 2 and then from 2 to 1. These iterations draw the granularity range from excessively fine-grained (iter₀) to excessively coarse-grained (iter₃) splitting. In literature, the initial iteration (iter₀), where each sub-circuit is a-=n individual gate, is used for LUT-based obfuscation, and the final iteration (iter_{N}), where the sub-circuit is the whole IP/module, is used for eFPGA-based redaction. Embodiments herein initiate an exploration by redaction of sub-circuits from iter₁₋₂, showing that the definition of granularity can affect the overhead significantly while it still guarantees robustness. It will be appreciated that N (the final iteration) depends on the size of the circuit. In larger circuits, more iteration may be required for splitting and N may become larger.

### Sub-Circuits Coloring and Scoring

Moving from coarse-grained to fine-grained redaction opens the possibility of acting selectively for the redaction point. So, after splitting, a unique strategy selection is utilized herein based on graph coloring to find the suited sub-circuits—the strategy is referred to herein as redaction-oriented conflict graph coloring (RoCGC). Two sub-circuits have conflict in embodiments herein if they are directly connected. RoCGC is used herein to color sub-circuits in a way that sub-circuits with a conflict must have different colors. FIGS. 5A-5D show how coloring (e.g., depicted in FIGS. 5A-5D with different angles of lines within the circles) may be applied on ISCAS-85 c17 throughout different iterations. RoCGC helps prioritize LUT-based redaction. This conflict graph coloring method helps identify the set of sub-circuits with less interference among themselves. When sub-circuits with minimal interference are redacted, the attacker must encounter each sub-circuit individually diverging towards a more brute-force scenario (non-correlative-based).

This is also highly possible (almost in all cases) that the designer may have more than enough sub-circuits for redaction. Hence, embodiments herein deploy a structural interference-based scoring mechanism that captures the interaction of the conflict sub-circuits with the other neighboring sub-circuits. The score of a given sub-circuit k in iterⱼ can be calculated by equation 1. Both RoCGC and score_{k|j} are defined in a way that the selected sub-circuits provide a reasonable corruptibility (not too high to be against the SAT and not too low to be against structural attacks), while the correlation between sub-circuits are low enough making any form of (either structural or non-structural) pre-processing for de-obfuscation impractical.

$${score}_{k \vert j} = {nodes}_{total} \times {w}_{ckt} \frac{{subckt}_{connected}}{n} + \frac{{subckt}_{connected}}{n} ( 1 - {w}_{ckt} ) {\sum }_{i = 0}^{n} \frac{{nodes}_{connected}}{{nodes}_{{ckt}_{i}}} \qquad ( 1 )$$

In Equation 1, w_{ckt} is weight of circuit, subckt_{connected} is number of circuits connected to circuit k, nodes_{connected} is number of nodes in circuit i connected with k, nodes_{ckti}, is number of nodes in circuit i, n is the total number of circuits in iterⱼ. Note that w_{ckt} is a coefficient defining the attribute to focus on for redaction. When w_{ckt} is high, the score of sub-circuit k is high if sub-circuit k has more connections with other neighboring sub-circuits (sub-circuit-level connection). Conversely, when the w_{ckt} is low, the score of sub-circuit k is high if the nodes of sub-circuit k have more connections with other sub-circuits' nodes (node-level connection). This unique definition configured by coefficient w_{ckt} allows the designer to select the sub-circuits based on both node-level and circuit-level attributes. It will be appreciated that, to avoid loss of generality, experiments herein aim to draw the impact of granularity on redaction overhead and robustness.

### Granular Redaction

After splitting, coloring, and scoring the sub-circuits, a sorted list of disintegrated sub-circuits are available for redaction. Unlike eFPGA-based redaction that employ only 1-2 eFPGA instances (due to huge overhead), since sub-circuit to LUT replacement incurs less overhead, multiple (5-150) sub-circuits are selected for the redaction. It will be appreciated that, in some cases, based on the topological structure of selected sub-circuit, the area of redacted design is less.

### Security Analysis of Embodiments Herein

Since embodiments herein involve a redaction-based technique, even though it is fine-grained, the assumptions and requirements of the security analysis are in line with other redaction techniques, such as eFPGA-based redaction. Hence, the focus of the security analysis and attack evaluation is on the SAT attack as it is the only applicable state-of-the-art attack on the redaction-based techniques. For instance, (i) since the circuit is redacted (specification and functional parts are redacted), none of the feature-based ML-based attacks are applicable; (ii) removal-based and structural-based are not applicable as the structural and functional are concealed together, and removing LUT(s) will result in malfunctioning; and (iii) re-synthesis-based attacks are not applicable as applying the key to LUTs does not reduce it to any form close to the original circuit.

By defining the range of granularity, how the number (and the size) of selected sub-circuits affect SAT resilience as well as area overhead are investigated.

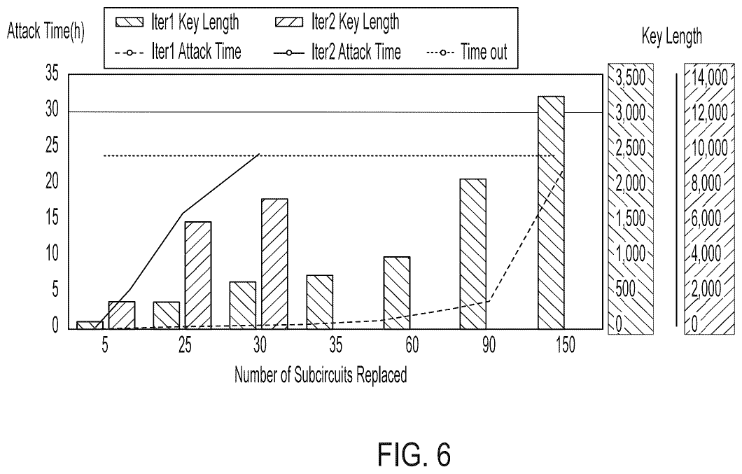

FIG. 6 shows a simple yet crucial sweep in LUT-based redaction using embodiments herein. Here for benchmark circuit Arbiter, after applying the splitting, coloring, and scoring, the number of redactions were swept to evaluate its impact on SAT attack time as well as the key size. Following are some of the important takeaways from this observation:
(i) As the number of redactions increases, the SAT attack time increases in a way that is somewhere between quadratic and exponential regression models (acceptable accuracy). As it follows fine-granularity, it allows the designer to tune the redaction using a more systematic method in order to achieve the desired robustness. This is the opposite of eFGPA-based redactions, where the designers must insert at least one huge fabric to determine whether it is robust enough.
(ii) The level of granularity has a crucial impact on area overhead, attack time, as well as key length. FIG. 6 shows two different iterations of embodiments herein (iter₁ and iter₂). Higher iterations (more coarse redaction) can achieve robustness with a very small number of sub-circuits redacted using LUTs (from 175 in iter₁ to only 20 in iter₂). It is evident for iter>2, the total number of redactions (to be resilient) becomes less and less, leading to the most coarse-grained (whole circuit), which requires only 1 (or 2) to be resilient. However, it affects the overhead negatively (making the higher iterations less efficient).
(iii) Key length is completely dependent on the level of granularity. For higher iterations in which the sub-circuits are bigger, the configuration size increases exponentially, and accordingly, when the redaction is more coarse-grained, the key length is much higher. As shown in FIG. 6, for iter₁, the minimum number of redaction resilient against the SAT requires ˜3.2K key bits. However, in iter₂, ˜7.2K key bits are required for the redacted sub-circuits. This observation is consistent with eFPGA-based redaction as a coarse-grained model, where >200K key bits are required for the same circuit.

### Experimental Results

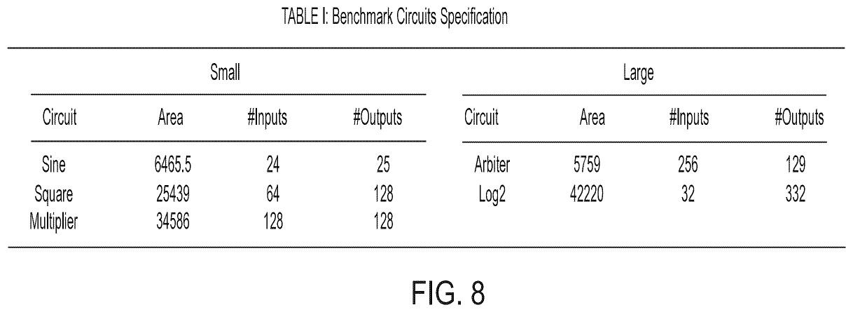

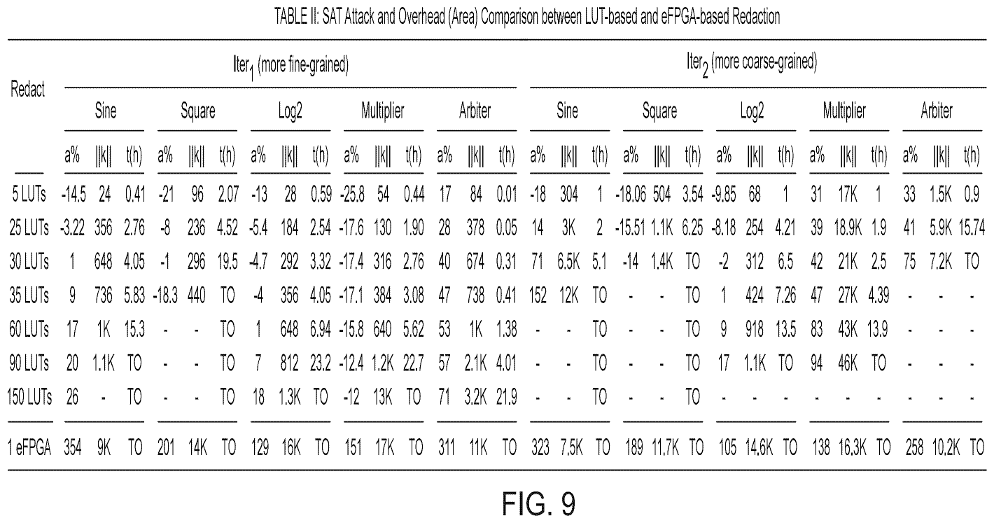

To investigate the security resiliency and performance overhead of various embodiments herein, a set of widely used combinational benchmarks were redacted, shown in TABLE I (FIG. 8) by following fine-grained redaction according to embodiments herein. The results were compared with eFPGA-based redaction. The experimental results are shown in TABLE II (FIG. 9). All SAT attack experiments were run with a timeout of 24 hours on a server with a 32-core 2.6 GHz Intel Xeon CPU and 64 GB RAM.

For each benchmark shown in Table I, the circuit splitter tool described herein was first applied to disintegrate the whole circuit into smaller subcircuits with different levels of granularity (iter₁, iter₂, . . . , etc.). Afterward, to assess the impact of granularity in redaction towards SAT resiliency and area overhead, iter₁ and iter₂ outcomes of the circuit splitter tool were selected. At iter₁, splitting is more granular, generating a larger number of smaller subcircuits, while at iter₂ splitting is more coarse, generating a smaller number of larger subcircuits. For each iteration (iter₁ and iter₂) across different benchmarks, as mentioned in the first two rows of TABLE II, the number of selected subcircuits for redaction (first column of TABLE II) were varied, the selected subcircuits were replaced by the same number of LUTs based on their I/O bandwidth, and a SAT attack was performed until a timeout (24 hours) was reached. For each of the different number of redactions as presented in different rows of Table II, their associated area overhead (a %), key size (∥k∥), and SAT attack execution time (t(h)) is reported in different columns. The number of redactions was continuously increased until a timeout was met. Once a timeout is met, a similar scenario was replaced in eFPGA-based coarse-grained redaction by implementing an exactly same size redaction in eFPGA and the associated area overhead, bitstream size, and SAT attack execution time were reported. For instance, timeout was met for iter₁ of Sine benchmark for 60 subcircuits redaction. Hence, a circuit in eFPGA was implemented whose area is equivalent to the total area of those 60 subcircuits (see TABLE II).
(i) Number of Redactions: For each benchmark and different iterations, area overhead, key size, and SAT attack time increase as more subcircuits are redacted.
(ii) Granularity: For every benchmark, the timeout was met at iter₂ with fewer redactions than iter₁, due to the larger subcircuit redactions at iter₂; however, it came out at the cost of more area overhead. Hence, better SAT resiliency can be achieved with more fine-grained redactions.
(iii) eFPGA-based redaction: Being the most coarse-grained form of redaction in the spectrum, requires less number of subcircuits to be redacted for SAT resiliency but incurs maximum overhead similar to the existing literature.

The above observations are also eminent for later iterations (more coarse-grained redaction) leading up to the whole circuit redaction. Embodiments herein demonstrate that fine-grained redactions offer better area overhead with less SAT resiliency which is the opposite of coarse-grained redaction. Therefore, a balance must be satisfied to achieve the target area overhead and SAT resiliency while utilizing circuit redaction against IP piracy using universal circuits.

Embodiments herein explore the impact of real fine to coarse granularity on the efficacy of IP redaction techniques and provide for a distinct and significantly more fine-grained redaction methodology using smaller reconfigurable components (LUTs). In embodiments herein, a splitting, coloring, and redaction mechanism is defined that efficiently allows for applying redaction at an appropriate granularity. Embodiments herein demonstrate that IP redaction at an appropriate granularity provides the same resiliency at significantly lower overhead.

### Example System Framework

FIG. 10 provides an example overview of a system 100 that can be used to practice embodiments of the present disclosure. The system 100 includes a system 101 comprising a computing entity 106. The system 101 may communicate with one or more external computing entities 102A-N using one or more communication networks. Examples of communication networks include any wired or wireless communication network including, for example, a wired or wireless local area network (LAN), personal area network (PAN), metropolitan area network (MAN), wide area network (WAN), or the like, as well as any hardware, software and/or firmware required to implement it (e.g., network routers, and/or the like).

The system 100 includes a storage subsystem 108 configured to store at least a portion of the data utilized by the system 101. The computing entity 106 may be in communication with the external computing entities 102A-N.

The storage subsystem 108 may be configured to store the model definition data store and the training data store for one or more machine learning models. The computing entity 106 may be configured to receive requests and/or data from at least one of the external computing entities 102A-N, process the requests and/or data to generate outputs, and provide the outputs to at least one of the external computing entities 102A-N. In some embodiments, the external computing entity 102A, for example, may periodically update/provide raw and/or processed input data to the system 101. The external computing entities 102A-N may further generate user interface data (e.g., one or more data objects) corresponding to the outputs and may provide (e.g., transmit, send, and/or the like) the user interface data corresponding with the outputs for presentation to the external computing entity 102A (e.g., to an end-user).

The storage subsystem 108 may be configured to store at least a portion of the data utilized by the computing entity 106 to perform one or more steps/operations and/or tasks described herein. The storage subsystem 108 may be configured to store at least a portion of operational data and/or operational configuration data including operational instructions and parameters utilized by the computing entity 106 to perform the one or more steps/operations described herein. The storage subsystem 108 may include one or more storage units, such as multiple distributed storage units that are connected through a computer network. Each storage unit in the storage subsystem 108 may store at least one of one or more data assets and/or one or more data about the computed properties of one or more data assets. Moreover, each storage unit in the storage subsystem 108 may include one or more non-volatile storage or memory media including but not limited to hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

The computing entity 106 can include an analysis engine and/or a training engine. The analysis engine may be configured to perform one or more data analysis techniques. The training engine may be configured to train the analysis engine in accordance with the data store stored in the storage subsystem 108.

### Example Computing Entity

FIG. 11 provides an example computing entity 106 in accordance with some embodiments discussed herein. In general, the terms computing entity, computer, entity, device, system, and/or similar words used herein interchangeably may refer to, for example, one or more computers, computing entities, desktops, mobile phones, tablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, steps/operations, and/or processes described herein. Such functions, steps/operations, and/or processes may include, for example, transmitting, receiving, operating on, processing, displaying, storing, determining, creating/generating, monitoring, evaluating, comparing, and/or similar terms used herein interchangeably. In one embodiment, these functions, steps/operations, and/or processes can be performed on data, content, information, and/or similar terms used herein interchangeably.

The computing entity 106 may include a network interface 220 for communicating with various computing entities, such as by communicating data, content, information, and/or similar terms used herein interchangeably that can be transmitted, received, operated on, processed, displayed, stored, and/or the like.

In one embodiment, the computing entity 106 may include or be in communication with a processing element 205 (also referred to as processors, processing circuitry, and/or similar terms used herein interchangeably) that communicate with other elements within the computing entity 106 via a bus, for example. As will be understood, the processing element 205 may be embodied in a number of different ways including, for example, as at least one processor/processing apparatus, one or more processors/processing apparatuses, and/or the like.

For example, the processing element 205 may be embodied as one or more complex programmable logic devices (CPLDs), microprocessors, multi-core processors, coprocessing entities, application-specific instruction-set processors (ASIPs), microcontrollers, and/or controllers. Further, the processing element 205 may be embodied as one or more other processing devices or circuitry. The term circuitry may refer to an entirely hardware embodiment or a combination of hardware and computer program products. Thus, the processing element 205 may be embodied as integrated circuits, application specific integrated circuits (ASICs), field programmable gate arrays (FPGAs), programmable logic arrays (PLAs), hardware accelerators, other circuitry, and/or the like.

As will therefore be understood, the processing element 205 may be configured for a particular use or configured to execute instructions stored in one or more memory elements including, for example, one or more volatile memories 215 and/or non-volatile memories 210. As such, whether configured by hardware or computer program products, or by a combination thereof, the processing element 205 may be capable of performing steps or operations according to embodiments of the present disclosure when configured accordingly. The processing element 205, for example in combination with the one or more volatile memories 215 and/or or non-volatile memories 210, may be capable of implementing one or more computer-implemented methods described herein. In some implementations, the computing entity 106 can include a computing apparatus, the processing element 205 can include at least one processor of the computing apparatus, and the one or more volatile memories 215 and/or non-volatile memories 210 can include at least one memory including program code. The at least one memory and the program code can be configured to, upon execution by the at least one processor, cause the computing apparatus to perform one or more steps/operations described herein.

The non-volatile memories 210 (also referred to as non-volatile storage, memory, memory storage, memory circuitry, media, and/or similar terms used herein interchangeably) may include at least one non-volatile memory device 210, including but not limited to hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

As will be recognized, the non-volatile memories 210 may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

The one or more volatile memories 215 (also referred to as volatile storage, memory, memory storage, memory circuitry, media, and/or similar terms used herein interchangeably) can include at least one volatile memory device, including but not limited to RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like.

As will be recognized, the volatile memories 215 may be used to store at least portions of the databases, database instances, database management systems, data, applications, programs, program modules, scripts, source code, object code, byte code, compiled code, interpreted code, machine code, executable instructions, and/or the like being executed by, for example, the processing element 205. Thus, the databases, database instances, database management systems, data, applications, programs, program modules, scripts, source code, object code, byte code, compiled code, interpreted code, machine code, executable instructions, and/or the like may be used to control certain embodiments of the operation of the computing entity 106 with the assistance of the processing element 205.

As indicated, in one embodiment, the computing entity 106 may also include the network interface 220 for communicating with various computing entities, such as by communicating data, content, information, and/or the like that can be transmitted, received, operated on, processed, displayed, stored, and/or the like. Such communication data may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 106 may be configured to communicate via wireless client communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

### Example External Computing Entity

FIG. 12 provides an example external computing entity 102A in accordance with some embodiments discussed herein. In general, the terms device, system, computing entity, entity, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, steps/operations, and/or processes described herein. The external computing entities 102A-N can be operated by various parties. As shown in FIG. 12, the external computing entity 102A can include an antenna 312, a transmitter 304 (e.g., radio), a receiver 306 (e.g., radio), and/or an external entity processing element 308 (e.g., CPLDs, microprocessors, multi-core processors, coprocessing entities, ASIPs, microcontrollers, and/or controllers) that provides signals to and receives signals from the transmitter 304 and the receiver 306, correspondingly. As will be understood, the external entity processing element 308 may be embodied in a number of different ways including, for example, as at least one processor/processing apparatus, one or more processors/processing apparatuses, and/or the like as described herein with reference to the processing element 205.

The signals provided to and received from the transmitter 304 and the receiver 306, correspondingly, may include signaling information/data in accordance with air interface standards of applicable wireless systems. In this regard, the external computing entity 102A may be capable of operating with one or more air interface standards, communication protocols, modulation types, and access types. More particularly, the external computing entity 102A may operate in accordance with any of a number of wireless communication standards and protocols, such as those described above with regard to the computing entity 106. In a particular embodiment, the external computing entity 102A may operate in accordance with multiple wireless communication standards and protocols, such as UMTS, CDMA2000, 1×RTT, WCDMA, GSM, EDGE, TD-SCDMA, LTE, E-UTRAN, EVDO, HSPA, HSDPA, Wi-Fi, Wi-Fi Direct, WiMAX, UWB, IR, NFC, Bluetooth, USB, and/or the like. Similarly, the external computing entity 102A may operate in accordance with multiple wired communication standards and protocols, such as those described above with regard to the computing entity 106 via an external entity network interface 320.

Via these communication standards and protocols, the external computing entity 102A can communicate with various other entities using means such as Unstructured Supplementary Service Data (USSD), Short Message Service (SMS), Multimedia Messaging Service (MMS), Dual-Tone Multi-Frequency Signaling (DTMF), and/or Subscriber Identity Module Dialer (SIM dialer). The external computing entity 102A can also download changes, add-ons, and updates, for instance, to its firmware, software (e.g., including executable instructions, applications, program modules), operating system, and/or the like.

According to one embodiment, the external computing entity 102A may include location determining embodiments, devices, modules, functionalities, and/or the like. For example, the external computing entity 102A may include outdoor positioning embodiments, such as a location module adapted to acquire, for example, latitude, longitude, altitude, geocode, course, direction, heading, speed, universal time (UTC), date, and/or various other information/data. In one embodiment, the location module can acquire data such as ephemeris data, by identifying the number of satellites in view and the relative positions of those satellites (e.g., using global positioning systems (GPS)). The satellites may be a variety of different satellites, including Low Earth Orbit (LEO) satellite systems, Department of Defense (DOD) satellite systems, the European Union Galileo positioning systems, the Chinese Compass navigation systems, Indian Regional Navigational satellite systems, and/or the like. This data can be collected using a variety of coordinate systems, such as the Decimal Degrees (DD); Degrees, Minutes, Seconds (DMS); Universal Transverse Mercator (UTM); Universal Polar Stereographic (UPS) coordinate systems; and/or the like. Alternatively, the location information/data can be determined by triangulating a position of the external computing entity 102A in connection with a variety of other systems, including cellular towers, Wi-Fi access points, and/or the like. Similarly, the external computing entity 102A may include indoor positioning embodiments, such as a location module adapted to acquire, for example, latitude, longitude, altitude, geocode, course, direction, heading, speed, time, date, and/or various other information/data. Some of the indoor systems may use various position or location technologies including RFID tags, indoor beacons or transmitters, Wi-Fi access points, cellular towers, nearby computing devices (e.g., smartphones, laptops) and/or the like. For instance, such technologies may include the iBeacons, Gimbal proximity beacons, Bluetooth Low Energy (BLE) transmitters, NFC transmitters, and/or the like. These indoor positioning embodiments can be used in a variety of settings to determine the location of someone or something to within inches or centimeters.

The external computing entity 102A may include a user interface 316 (e.g., a display, speaker, and/or the like) that can be coupled to the external entity processing element 308. In addition, or alternatively, the external computing entity 102A can include a user input interface 319 (e.g., keypad, touch screen, microphone, and/or the like) coupled to the external entity processing element 308).

For example, the user interface 316 may be a user application, browser, and/or similar words used herein interchangeably executing on and/or accessible via the external computing entity 102A to interact with and/or cause the display, announcement, and/or the like of information/data to a user. The user input interface 318 can comprise any of a number of input devices or interfaces allowing the external computing entity 102A to receive data including, as examples, a keypad (hard or soft), a touch display, voice/speech interfaces, motion interfaces, and/or any other input device. In embodiments including a keypad, the keypad can include (or cause display of) the conventional numeric (0-9) and related keys (#, *, and/or the like), and other keys used for operating the external computing entity 102A and may include a full set of alphabetic keys or set of keys that may be activated to provide a full set of alphanumeric keys. In addition to providing input, the user input interface 318 can be used, for example, to activate or deactivate certain functions, such as screen savers, sleep modes, and/or the like.

The external computing entity 102A can also include one or more external entity non-volatile memories 322 and/or one or more external entity volatile memories 324, which can be embedded within and/or may be removable from the external computing entity 102A. As will be understood, the external entity non-volatile memories 322 and/or the external entity volatile memories 324 may be embodied in a number of different ways including, for example, as described herein with reference to the non-volatile memories 210 and/or the external volatile memories 215.

The terms “data,” “content,” “digital content,” “digital content object,” “signal,” “information,” and similar terms may be used interchangeably to refer to data capable of being transmitted, received, and/or stored in accordance with embodiments of the present disclosure. Thus, use of any such terms should not be taken to limit the spirit and scope of embodiments of the present disclosure. Further, where a computing device is described herein to receive data from another computing device, it will be appreciated that the data may be received directly from another computing device or may be received indirectly via one or more intermediary computing devices, such as, for example, one or more servers, relays, routers, network access points, base stations, hosts, and/or the like, sometimes referred to herein as a “network.” Similarly, where a computing device is described herein to send data to another computing device, it will be appreciated that the data may be transmitted directly to another computing device or may be transmitted indirectly via one or more intermediary computing devices, such as, for example, one or more servers, relays, routers, network access points, base stations, hosts, and/or the like.

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

1. A method, comprising:
receiving a register-transfer-level (RTL) description of an integrated circuit (IC) asset;
generating a split RTL description comprising a plurality of sub-circuits by splitting the RTL description of the IC asset; and
generating a plurality of replaced sub-circuits by replacing a subset of the plurality of sub-circuits with multiplexor (MUX)-based lookup-tables (LUTs), wherein the plurality of sub-circuits comprises the plurality of replaced sub-circuits and a plurality of unreplaced sub-circuits.

2. The method of claim 1, wherein determining the subset of the plurality of sub-circuits to replace with MUX-based LUTs comprises:
identifying, based at least in part on performing a conflict graph coloring, non-interference sub-circuits of the plurality of sub-circuits, wherein a non-interference sub-circuit comprises a sub-circuit with non-interference sub-circuit interaction with other sub-circuits;
generating a plurality of scores by generating a score for each non-interference sub-circuit and based at least in part on the non-interference sub-circuit interaction with other sub-circuits; and
based at least in part on a desired number of sub-circuits to replace and the plurality of scores, determining the subset.

3. The method of claim 1, wherein the plurality of sub-circuits is instantiated to reconstruct a functionality of the IC asset.

4. The method of claim 1, wherein a higher score represents more interaction by a sub-circuit with neighboring sub-circuits relative to other sub-circuits.

5. The method of claim 1, further comprising:
generating, based at least in part on the plurality of replaced sub-circuits and the plurality of unreplaced sub-circuits, a MUX-tree-based universal circuit for a given I/O bandwidth of the plurality of sub-circuits and bitstreams associated therewith.

6. The method of claim 5, wherein generating the MUX-tree-based universal circuit comprises using a parser.

7. The method of claim 5, further comprising:
generating a realized IC asset by realizing the IC asset based at least in part on integrating the MUX-tree-based universal circuit using the split RTL description.

8. The method of claim 7, wherein the realized IC asset continues to one or more of logic synthesis, physical layout, or fabrication of an ASIC design flow.

9. The method of claim 8, subsequent to packaging the realized IC asset into an individual IC, unlocking, based at least in part on an earlier generated bitstream, LUT-based redacted functionality of the IC asset.

10. An apparatus comprising at least one memory and one or more processors that, with the at least one memory, configure the apparatus to:
receive a register-transfer-level (RTL) description of an integrated circuit (IC) asset;
generate a split RTL description comprising a plurality of sub-circuits by splitting the RTL description of the IC asset; and
generate a plurality of replaced sub-circuits by replacing a subset of the plurality of sub-circuits with multiplexor (MUX)-based lookup-tables (LUTs), wherein the plurality of sub-circuits comprises the plurality of replaced sub-circuits and a plurality of unreplaced sub-circuits.

11. The apparatus of claim 10, wherein determining the subset of the plurality of sub-circuits to replace with MUX-based LUTs comprises:
identifying, based at least in part on performing a conflict graph coloring, non-interference sub-circuits of the plurality of sub-circuits, wherein a non-interference sub-circuit comprises a sub-circuit with non-interference sub-circuit interaction with other sub-circuits;
generating a plurality of scores by generating a score for each non-interference sub-circuit and based at least in part on the non-interference sub-circuit interaction with other sub-circuits; and
based at least in part on a desired number of sub-circuits to replace and the plurality of scores, determining the subset.

12. The apparatus of claim 10, wherein the plurality of sub-circuits is instantiated to reconstruct a functionality of the IC asset.

13. The apparatus of claim 10, wherein a higher score represents more interaction by a sub-circuit with neighboring sub-circuits relative to other sub-circuits.

14. The apparatus of claim 10, wherein the apparatus is further configured to:
generating, based at least in part on the plurality of replaced sub-circuits and the plurality of unreplaced sub-circuits, a MUX-tree-based universal circuit for a given I/O bandwidth of the plurality of sub-circuits and bitstreams associated therewith.

15. The apparatus of claim 14, wherein generating the MUX-tree-based universal circuit comprises using a parser.

16. The apparatus of claim 14, further comprising:
generating a realized IC asset by realizing the IC asset based at least in part on integrating the MUX-tree-based universal circuit using the split RTL description.

17. The apparatus of claim 16, wherein the realized IC asset continues to one or more of logic synthesis, physical layout, or fabrication of an ASIC design flow.

18. At least one non-transitory computer-readable storage medium comprising instructions that, when executed by one or more processors, cause the one or more processors to:
receive a register-transfer-level (RTL) description of an integrated circuit (IC) asset;
generate a split RTL description comprising a plurality of sub-circuits by splitting the RTL description of the IC asset; and
generate a plurality of replaced sub-circuits by replacing a subset of the plurality of sub-circuits with multiplexor (MUX)-based lookup-tables (LUTs), wherein the plurality of sub-circuits comprises the plurality of replaced sub-circuits and a plurality of unreplaced sub-circuits.

19. The at least one non-transitory computer-readable storage medium of claim 18, wherein determining the subset of the plurality of sub-circuits to replace with MUX-based LUTs comprises:
identifying, based at least in part on performing a conflict graph coloring, non-interference sub-circuits of the plurality of sub-circuits, wherein a non-interference sub-circuit comprises a sub-circuit with non-interference sub-circuit interaction with other sub-circuits;
generating a plurality of scores by generating a score for each non-interference sub-circuit and based at least in part on the non-interference sub-circuit interaction with other sub-circuits; and
based at least in part on a desired number of sub-circuits to replace and the plurality of scores, determining the subset.

20. The at least one non-transitory computer-readable storage medium of claim 18, wherein a higher score represents more interaction by a sub-circuit with neighboring sub-circuits relative to other sub-circuits.
